(19) United States
(12) Patent Application Publication
(10) Pub. No.: US 2025/0169108 A1
(43) Pub. Date: May 22, 2025

(54) INTEGRATED CIRCUIT DEVICE AND METHOD OF MANUFACTURING THE SAME

(71) Applicant: SAMSUNG ELECTRONICS CO., LTD., SUWON-SI (KR)

(72) Inventors: Taesun Kim, Suwon-si (KR); Sangjine Park, Suwon-si (KR); Youngjun Kim, Suwon-si (KR)

(21) Appl. No.: 18/938,703

(22) Filed: Nov. 6, 2024

(30) Foreign Application Priority Data
Nov. 21, 2023 (KR) 10-2023-0162732

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/017

(57) ABSTRACT

An integrated circuit device includes a fin-type active region extending in a first horizontal direction on a substrate, a gate line disposed on the fin-type active region on the substrate and extending in a second horizontal direction intersecting the first horizontal direction, a source/drain region disposed on the fin-type active region and disposed adjacent to the gate line in the first horizontal direction, a source/drain contact disposed on the source/drain region, an upper insulating structure disposed on the gate line and including an etch stop film and an interlayer insulating film, a source/drain via contact passing through the upper insulating structure and connected to the source/drain contact, and an air gap disposed between the etch stop film and the source/drain via contact and overlapping a part of the source/drain via contact in a horizontal direction.

### CROSS-REFERENCE TO RELATED APPLICATION

This application is based on and claims priority under 35 U.S.C. § 119 to Korean Patent Application No. 10-2023-0162732, filed on Nov. 21, 2023, in the Korean Intellectual Property Office, the disclosure of which is incorporated by reference herein in its entirety.

### BACKGROUND

### 1. Technical Field

The inventive concept relates to an integrated circuit device and a method of manufacturing the same.

### 2. Discussion of Related Art

The development of the electronics industry has led to high capacity and high integration of integrated circuit devices. As capacity and integration of the integrated circuit devices increases, reliability of the integrated circuit devices needs to be ensured.

### SUMMARY

The inventive concept provides an integrated circuit device with improved functional characteristics and electrical reliability and a method of manufacturing the integrated circuit device.

According to an aspect of the inventive concept, there is provided an integrated circuit device including a fin-type active region extending in a first horizontal direction on a substrate, a gate line disposed on the fin-type active region on the substrate and extending in a second horizontal direction intersecting the first horizontal direction, a source/drain region disposed on the fin-type active region and disposed adjacent to the gate line in the first horizontal direction, a source/drain contact disposed on the source/drain region, an upper insulating structure disposed on the gate line and including an etch stop film and an interlayer insulating film, a source/drain via contact passing through the upper insulating structure and connected to the source/drain contact, and an air gap disposed between the etch stop film and the source/drain via contact and overlapping a part of the source/drain via contact in a horizontal direction.

According to another aspect of the inventive concept, there is provided a method of manufacturing an integrated circuit device, the method including forming a source/drain region on a substrate and a source/drain contact on the source/drain region, forming, on the source/drain contact, an upper insulating structure including an etch stop film and an interlayer insulating film disposed on the etch stop film, forming a via hole in the interlayer insulating film, forming a horizontal recess in the etch stop film, forming a recess portion in a part of the source/drain contact, and forming a source/drain via contact in the recess portion, in a portion of the horizontal recess, and in the via hole.

According to another aspect of the inventive concept, there is provided an integrated circuit device including a fin-type active region extending in a first horizontal direction on a substrate, a nanosheet stack facing a fin top surface of the fin-type active region at a position spaced apart from the fin top surface in a vertical direction and including at least one nanosheet, a gate line surrounding the at least one nanosheet on the fin-type active region and extending in a second horizontal direction intersecting the first horizontal direction, a source/drain region disposed on the fin-type active region and disposed adjacent to the gate line in the first horizontal direction, a source/drain contact disposed on the source/drain region, a gate dielectric film contacting a bottom surface and side walls of the gate line, a pair of insulating spacers disposed on the side walls of the gate line and spaced apart from the gate line in the first horizontal direction with the gate dielectric film disposed therebetween, a capping insulating pattern disposed on a top surface of the gate line and a top surface of the gate dielectric film, and between the pair of insulating spacers, an upper insulating structure disposed on the capping insulating pattern and the gate line and including an etch stop film and an interlayer insulating film, and a source/drain via contact passing through the upper insulating structure and connected to the source/drain contact, wherein the source/drain via contact includes an upper area passing through the interlayer insulating film, and a lower area disposed at a lower end portion of the upper area and passing through the etch stop film, wherein the etch stop film includes an air gap surrounding the lower area in a horizontal direction and overlapping the lower area in the horizontal direction.

### BRIEF DESCRIPTION OF THE DRAWINGS

Embodiments will be more clearly understood from the following detailed description taken in conjunction with the accompanying drawings in which:

FIG. 1 is a view illustrating a plan layout of a cell block of an integrated circuit device, according to an embodiment;

FIG. 2 is a plan layout diagram for describing an integrated circuit device, according to an embodiment;

FIG. 3 is a cross-sectional view taken along line X1-X1′ of FIG. 2;

FIG. 4 is an enlarged cross-sectional view illustrating a portion “EX1” of FIG. 3;

FIG. 5 is a cross-sectional view taken along line Y1-Y1′ of FIG. 2;

FIG. 6 is a cross-sectional view taken along line Y2-Y2′ of FIG. 2; and

FIGS. 7 to 19 are cross-sectional views illustrated according to a process order to describe a method of manufacturing an integrated circuit device, taken along line X1-X1′ of FIG. 2, according to an embodiment.

### DETAILED DESCRIPTION

Hereinafter, embodiments will be described in detail with reference to the accompanying drawings. The same components in the drawings are denoted by the same reference numerals, and repeated descriptions thereof may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

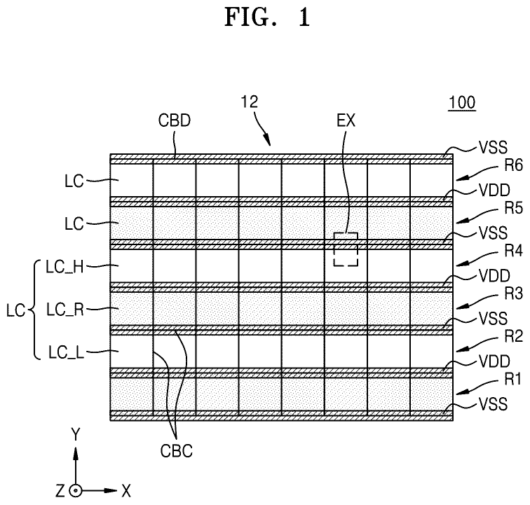

FIG. 1 is a view illustrating a plan layout of a cell block of an integrated circuit device, according to an embodiment.

Referring to FIG. 1, a cell block 12 of an integrated circuit device 100 may include a plurality of logic cells LC including circuit patterns forming various circuits. The plurality of logic cells LC may be arranged in a matrix along a first horizontal direction (X direction) and a second horizontal direction (Y direction) in the cell block 12.

The plurality of logic cells LC may have a function of performing various logic functions. The plurality of logic cells LC may include a circuit pattern having a layout designed according to a place and route (PnR) method to perform at least one logic function. In an embodiment, the plurality of logic cells LC may include a plurality of standard cells. In an embodiment, at least some of the plurality of logic cells LC may perform a same logic function. In some embodiments, at least some of the plurality of logic cells LC may perform different logic functions.

The plurality of logic cells LC may include various types of logic cells including a plurality of circuit elements. For example, each of the plurality of logic cells LC may include, but is not limited to, AND, NAND, OR, NOR, exclusive OR (XOR), exclusive NOR (XNOR), inverter (INV), adder (ADD), buffer (BUF), delay (DLY), filter (FIL), multiplexer (MXT/MXIT), OR/AND/INVERTER (OAI), AND/OR (A/O), AND/OR/INVERTER (AOI), a D flip-flop, a reset flip-flop, a master-slave flip-flop, a latch circuit element, or a combination thereof.

In the cell block 12, the plurality of logic cells LC may be disposed in a plurality of rows, including rows R1, R2, R3, R4, R5, or R6. The plurality of rows may have the same width along the first horizontal direction (X direction). Also, at least some of the plurality of logic cells LC may have a same height. However, the inventive concept is not limited to that illustrated in FIG. 1, and at least some of the plurality of logic cells LC may have different widths and heights.

An area of each of the plurality of logic cells LC included in the cell block 12 of the integrated circuit device 100 may be defined by a boundary CBD. A cell contact portion CBC may be disposed where the cell boundaries CBD meet. The cell contact portion CBC may be disposed between two logic cells LC adjacent to each other in the first horizontal direction (X direction) or the second horizontal direction (Y direction) from among the plurality of logic cells LC.

In an embodiment, two logic cells LC adjacent to each other in the first horizontal direction (X direction) and disposed in a row R1, R2, R3, R4, R5, or R6 may contact each other at the cell contact portion CBC without a space therebetween. In some embodiments, two logic cells LC adjacent to each other in the first horizontal direction (X direction) and disposed in a row R1, R2, R3, R4, R5, or R6 may be spaced apart from each other with a distance therebetween.

In an embodiment, in the plurality of logic cells LC of a row R1, R2, R3, R4, R5, or R6, two logic cells LC adjacent to each other may perform the same function. In this case, the two adjacent logic cells LC may have a same structure. In some embodiments, in the plurality of logic cells LC one of a row R1, R2, R3, R4, R5, or R6, two logic cells LC adjacent to each other may perform different functions.

In an embodiment, a logic cell LC selected from among the plurality of logic cells LC included in the cell block 12 of the integrated circuit device 100 and another logic cell LC adjacent to the selected logic cell LC in the second horizontal direction (Y direction) may be symmetrical to each other with the cell contact portion CBC disposed therebetween. For example, a reference logic cell LC_R in the third row R3 and a lower logic cell LC_L in the second row R2 may be symmetrical to each other with the cell contact portion CBC disposed therebetween. Also, the reference logic cell LC_R in the third row R3 and an upper logic cell LC_H in the fourth row R4 may be symmetrical to each other with the cell contact portion CBC disposed therebetween.

Although the cell block 12 includes six rows R1, R2, . . . , and R6 in FIG. 1, this is only an example. The cell block 12 may include a various number of rows, and a row may include a various number of logic cells.

The cell block 12 of the integrated circuit device 100 may include a plurality of ground lines VSS and a plurality of power supply lines VDD. One selected from among a plurality of ground lines VSS or a plurality of power supply lines VDD may be disposed between the plurality of rows R1, R2, R3, R4, R5, and R6 including the plurality of logic cells LC aligned along the first horizontal direction (X direction). The plurality of ground lines VSS and the plurality of power supply lines VDD may extend along the first horizontal direction (X direction) and may be alternately arranged to be spaced apart from each other along the second horizontal direction (Y direction). For example, the plurality of ground lines VSS and the plurality of power supply lines VDD may be alternately disposed between the plurality of rows R1, R2, R3, R4, R5, and R6 including the plurality of logic cells LC. Accordingly, each of the plurality of ground lines VSS and the plurality of power supply lines VDD may be disposed at the cell boundary CBD along the second horizontal direction (Y direction) of the logic cell LC.

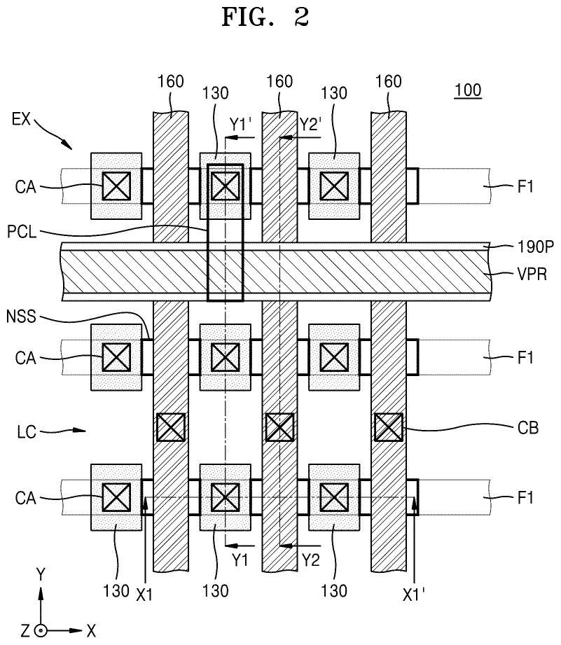

FIG. 2 is a plan layout diagram for describing an integrated circuit device, according to an embodiment.

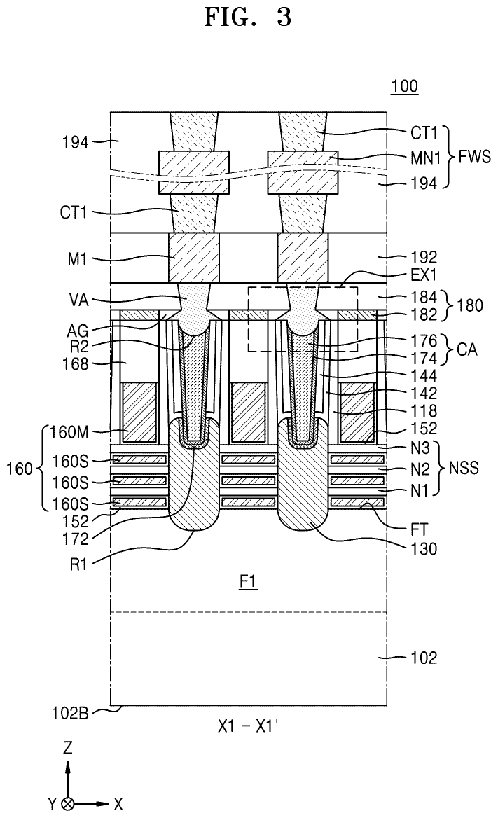

FIG. 3 is a cross-sectional view taken along line X1-X1′ of FIG. 2.

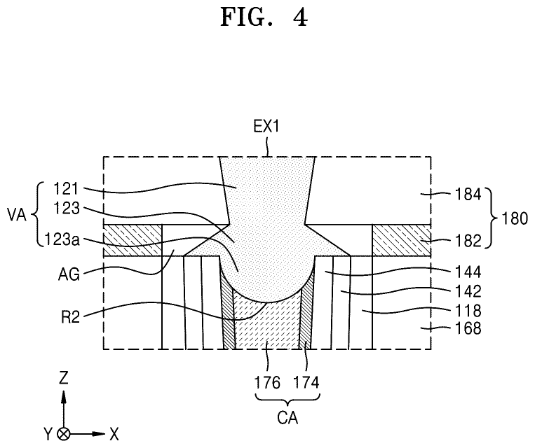

FIG. 4 is an enlarged cross-sectional view illustrating a portion “EX1” of FIG. 3.

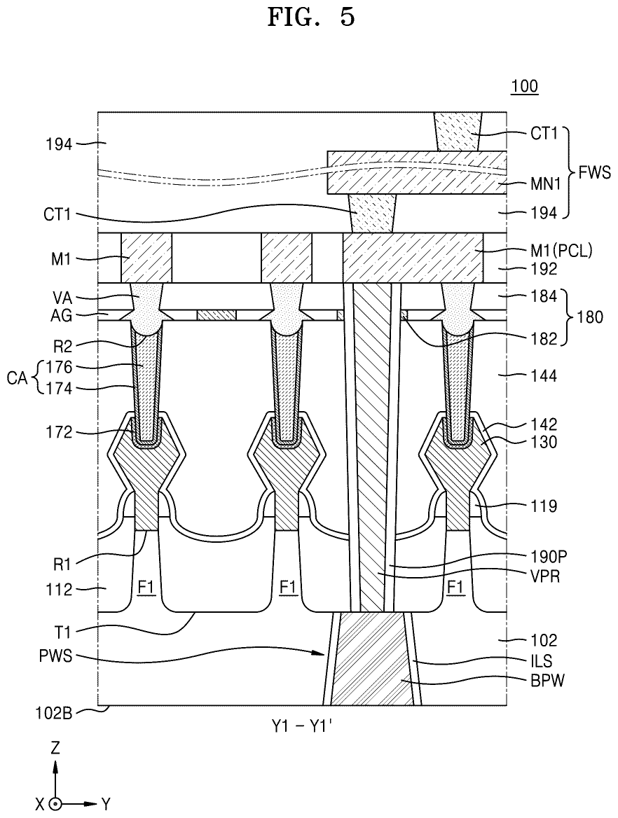

FIG. 5 is a cross-sectional view taken along line Y1-Y1′ of FIG. 2.

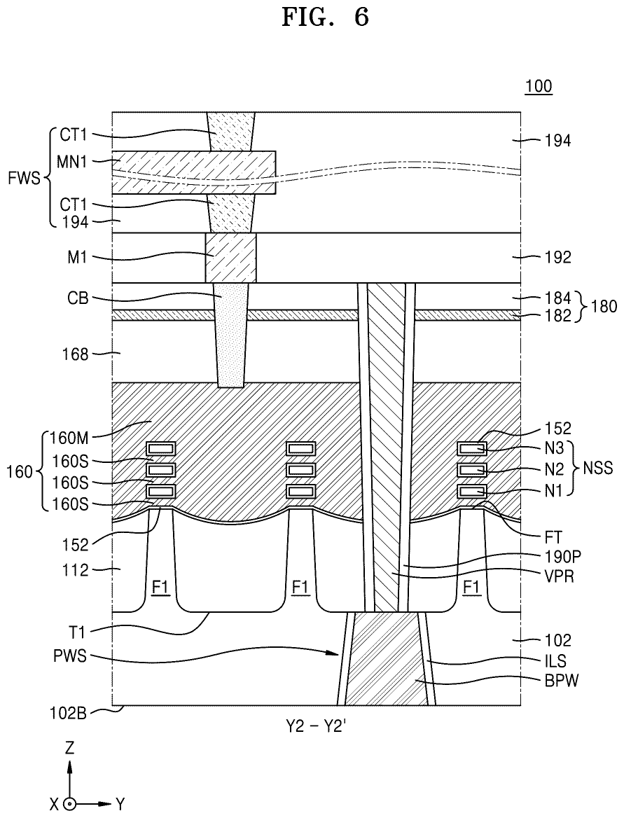

FIG. 6 is a cross-sectional view taken along line Y2-Y2′ of FIG. 2.

With reference to FIGS. 2 to 6, the integrated circuit device 100 including a field-effect transistor having a gate-all-around structure including an active region having a nanowire or nanosheet structure and a gate surrounding the active region will be described.

Referring to FIGS. 2 to 6, the integrated circuit device 100 may include two logic cells LC adjacent to each other in the second horizontal direction (Y direction) with a via power rail VPR disposed therebetween. In embodiments, the via power rail VPR may represent the ground line VSS of FIG. 1.

The integrated circuit device 100 may include a substrate 102 having a backside surface 102B, and a plurality of fin-type active regions F1 protruding from the substrate 102 (see FIG. 3). The plurality of fin-type active regions F1 may define a plurality of trench areas T1 in the substrate 102 opposite to the backside surface 102B. The plurality of fin-type active regions F1 may be arranged along the first horizontal direction (X direction) on the substrate 102, and the plurality of fin-type active regions F1 may extend parallel to each other in the second horizontal direction (Y direction).

The substrate 102 may include a semiconductor such as Si or Ge, or may include a compound semiconductor such as SiGe, SiC, GaAs, InAs, InGaAs, or InP. The terms “SiGe”, “SiC”, “GaAs”, “InAs”, “InGaAs”, and “InP” used herein each refer to a material including elements included in each term and may not refer to a chemical formula representing a stoichiometric relationship. The substrate 102 may include a conductive region, for example, a well doped with impurities or a structure doped with impurities.

A device isolation film 112 may be located in the trench area T1 (see FIG. 5). The device isolation film 112 may cover a at least a part of a side wall of each of the plurality of fin-type active regions F1 in the plurality of trench areas T1. The device isolation film 112 may be formed of, but not limited to, a silicon oxide film.

The via power rail VPR may extend in a vertical direction (Z direction) between a pair of fin-type active regions F1 selected from among the plurality of fin-type active regions F1 and adjacent to each other, and between a pair of source/drain regions 130 disposed on the a pair of fin-type active regions F1. The via power rail VPR may pass through the device isolation film 112 in the vertical direction (Z direction). For example, an upper surface of the via power rail VPR may be located at a height in the vertical direction (Z direction) that is higher than an upper surface of the device isolation film 112.

A via insulating spacer 190P may be disposed on a side wall of the via power rail VPR. For example, the side wall of the via power rail VPR may be surrounded by the via insulating spacer 190P. In some embodiments, the via power rail VPR may include a metal wiring layer and a conductive barrier layer surrounding the metal wiring layer. The metal wiring layer may be formed of Ru, Co, W, or a combination thereof. The conductive barrier layer may be formed of Ti, TiN, Ta, TaN, or a combination thereof. The via insulating spacer 190P may be formed of a material selected from among silicon nitride (SiN), silicon oxycarbide (SiOC), silicon oxynitride (SiON), or silicon oxycarbonitride (SiOCN). The terms “SiN”, “SiOC”, and “SiON” used herein each refer to a material including elements included in each term and may not refer to a chemical formula representing a stoichiometric relationship. For example, silicon nitride (SiN) may be Si3N4.

In an embodiment, the substrate 102 may include a backside power structure PWS. The backside power structure PWS may pass through the substrate 102 in the vertical direction (Z direction) at a position overlapping the via power rail VPR in the vertical direction (Z direction). The backside power structure PWS may include a backside power rail BPW and an insulating liner structure ILS covering side walls of the backside power rail BPW.

In an embodiment, each of the via insulating spacer 190P and the insulating liner structure ILS may be formed of silicon nitride (SiN), silicon oxycarbide (SiOC), silicon oxynitride (SiON), silicon oxycarbonitride (SiOCN), or a combination thereof. The terms “SiN”, “SiOC”, “SiON”, “SiOCN”, and “SiO” used herein each refer to a material including elements included in each term and may not refer to a chemical formula representing a stoichiometric relationship. In embodiments, silicon nitride (SiN) may be Si3N4. Silicon oxide (SiO) may be SiO2.

In some embodiments, the backside power rail BPW may include a metal wiring layer and a conductive barrier layer surrounding the metal wiring layer. A more detailed configuration of the metal wiring layer and the conductive barrier layer forming the backside power rail BPW may be substantially the same as that described for the metal wiring layer and the conductive barrier layer forming the via power rail VPR.

The backside power rail BPW may be spaced apart from a pair of source/drain regions 130 disposed on sides of the via power rail VPR with the device isolation film 112 disposed therebetween. The backside power structure PWS may be spaced apart from a pair of fin-type active regions F1 on sides of the via power rail VPR with the substrate 102 disposed therebetween. Accordingly, the backside power rail BPW may be spaced apart from a pair of source/drain regions 130 disposed on sides of the via power rail VPR with the device isolation film 112 disposed therebetween. The backside power structure PWS may be spaced apart from a pair of fin-type active regions F1 on sides of the via power rail VPR with the substrate 102 disposed therebetween. The insulating liner structure ILS may cover side walls of the backside power rail BPW in the second horizontal direction (Y direction). The backside power rail BPW may be spaced apart from a pair of fin-type active regions F1 disposed at sides of the via power rail VPR with the insulating liner structure ILS and the substrate 102 disposed therebetween.

A plurality of gate lines 160 may be disposed on the plurality of fin-type active regions F1 (see FIG. 3). The plurality of gate lines 160 may extend along the second horizontal direction (Y direction), which may be substantially perpendicular to the first horizontal direction (X direction). A plurality of nanosheet stacks NSS may be disposed on a fin top surface FT of each of the plurality of fin-type active regions F1 in areas where the plurality of fin-type active regions F1 and the plurality of gate lines 160 intersect each other. Each of the plurality of nanosheet stacks NSS may include at least one nanosheet facing the fin top surface FT at a position spaced apart from the fin top surface FT of the fin-type active region F1 in the vertical direction (Z direction). The term “nanosheet” used herein may refer to a conductive structure having a cross-section substantially perpendicular to a direction in which an electric current may flow. The nanosheet may include a nanowire.

The plurality of nanosheet stacks NSS may include a first nanosheet N1, a second nanosheet N2, and a third nanosheet N3 overlapping each other in the vertical direction (Z direction) in each fin-type active region F1. The first nanosheet N1, the second nanosheet N2, and the third nanosheet N3 may have different vertical distances (Z-direction distances) from the fin top surface FT of the fin-type active region F1. The plurality of gate lines 160 may surround the first nanosheet N1, the second nanosheet N2, and the third nanosheet N3 included in the nanosheet stack NSS overlapping in the vertical direction (Z direction).

Although the nanosheet stack NSS may have a substantially quadrangular planar shape in FIG. 2, the inventive concept is not limited thereto. The nanosheet stack NSS may have any of various planar shapes according to a planar shape of each of the fin-type active region F1 and the gate line 160. In an example, a plurality of nanosheet stacks NSS and a plurality of gate lines 160 may be disposed on a fin-type active region F1, and the plurality of nanosheet stacks NSS may be aligned along the first horizontal direction (X direction) on the a fin-type active region F1. However, the number of nanosheet stacks NSS and the number of gate lines 160 disposed on one fin-type active region F1 are not particularly limited.

Each of the first nanosheet N1, the second nanosheet N2, and the third nanosheet N3 included in the nanosheet stack NSS may function as a channel region. In an embodiment, each of the first nanosheet N1, the second nanosheet N2, and the third nanosheet N3 may have a thickness selected within a range of, but not limited to, about 4 nanometer (nm) to about 6 nm. A thickness of each of the first nanosheet N1, the second nanosheet N2, and the third nanosheet N3 may refer to a size along the vertical direction (Z direction). In embodiments, the first nanosheet N1, the second nanosheet N2, and the third nanosheet N3 may have substantially the same thickness along the vertical direction (Z direction). In some embodiments, at least some of the first nanosheet N1, the second nanosheet N2, and the third nanosheet N3 may have different thicknesses along the vertical direction (Z direction). In an embodiment, each of the first nanosheet N1, the second nanosheet N2, and the third nanosheet N3 included in the nanosheet stack NSS may include an Si layer, a SiGe layer, or a combination thereof.

The first nanosheet N1, the second nanosheet N2, and the third nanosheet N3 included in one nanosheet stack NSS may have the same size or similar sizes in the first horizontal direction (X direction). In some embodiments, at least some of the first nanosheet N1, the second nanosheet N2, and the third nanosheet N3 included in one nanosheet stack NSS may have different sizes in the first horizontal direction (X direction). Although each of a plurality of nanosheet stacks NSS includes three nanosheets in FIG. 3, the inventive concept is not limited thereto. For example, the nanosheet stack NSS may include at least one nanosheet, and the number of nanosheets forming the nanosheet stack NSS is not particularly limited.

Each of the plurality of gate lines 160 may include a main gate portion 160M and a plurality of sub-gate portions 160S. The main gate portion 160M may be disposed on a top surface of the nanosheet stack NSS. For example, the main gate portion 160M may cover a top surface of the nanosheet stack NSS and may extend along the second horizontal direction (Y direction). The plurality of sub-gate portions 160S may be integrally connected to the main gate portion 160M, and may each be disposed between the first nanosheet N1, the second nanosheet N2, and the third nanosheet N3 and disposed between the first nanosheet N1 and the fin-type active region F1. In the vertical direction (Z direction), a thickness of each of the plurality of sub-gate portions 160S may be less than a thickness of the main gate portion 160M.

A plurality of recesses R1 may be disposed in the fin-type active region F1. A vertical level of a lowermost surface of each of the plurality of recesses R1 may be lower than a vertical level of the fin top surface FT of the fin-type active region F1. The term “vertical level” used herein may refer to a distance from the backside surface 102B of the substrate 102 along the vertical direction (Z direction or −Z direction). Here, the −Z direction may be an direction opposite to the Z direction.

A plurality of source/drain regions 130 may be disposed in the plurality of recesses R1. Each of the plurality of source/drain regions 130 may be disposed at a position adjacent to at least one gate line 160 selected from among the plurality of gate lines 160. Each of the plurality of source/drain regions 130 may have surfaces facing the first nanosheet N1, the second nanosheet N2, and the third nanosheet N3 included in the adjacent nanosheet stack NSS (see FIG. 2). Each of the plurality of source/drain regions 130 may contact the first nanosheet N1, the second nanosheet N2, and the third nanosheet N3 included in the adjacent nanosheet stack NSS.

Each of the plurality of gate lines 160 may be formed of a metal, metal nitride, metal carbide, or a combination thereof. The metal may be selected from among Ti, W, Ru, Nb, Mo, Hf, Ni, Co, Pt, Yb, Tb, Dy, Er, or Pd. The metal nitride may be selected from among TiN or TaN. The metal carbide may be TiAlC. However, examples of a material for the plurality of gate lines 160 are not limited thereto.

A gate dielectric film 152 may be disposed between the nanosheet stack NSS and the gate line 160. In an embodiment, the gate dielectric film 152 may have a structure in which an interface dielectric film and a high-k dielectric film are stacked. The interface dielectric film may be formed of a low-k dielectric material film having a dielectric constant of about 9 or less, for example, a silicon oxide film, a silicon oxynitride film, or a combination thereof. In some embodiments, the interface dielectric film may be omitted. The high-k dielectric film may be formed of a material having a higher dielectric constant than a silicon oxide film. For example, the high-k dielectric film may have a dielectric constant of about 10 to 25. The high-k dielectric film may be formed of, but not limited to, hafnium oxide.

A capping insulating pattern 168 may be disposed on a top surface of each of the gate dielectric film 152 and the gate line 160. For example, the top surface of each of the gate dielectric film 152 and the gate line 160 may be covered by the capping insulating pattern 168. The capping insulating pattern 168 may be formed of a silicon nitride film. An outer insulating spacer 118 may be disposed on side walls of each of the gate line 160 and the capping insulating pattern 168. For example, side walls of each of the gate line 160 and the capping insulating pattern 168 may be covered by an outer insulating spacer 118. The outer insulating spacer 118 may cover side walls of the main gate portion 160M on the top surface of each of the plurality of nanosheet stacks NSS. The outer insulating spacer 118 may be spaced apart from the gate line 160 with the gate dielectric film 152 disposed therebetween.

A plurality of recessed side insulating spacers 119 disposed on side walls of the source/drain region 130 may be disposed on a top surface of the device isolation film 112. In some embodiments, each of the plurality of recessed side insulating spacers 119 may be integrally connected to the outer insulating spacer 118 disposed adjacent thereto.

Each of the plurality of outer insulating spacers 118 and the plurality of recessed side insulating spacers 119 may be formed of silicon nitride, silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC” used herein each refer to a material including elements included in each term and may not refer to a chemical formula representing a stoichiometric relationship.

A metal silicide film 172 may be disposed on a top surface of each of the plurality of source/drain regions 130. The metal silicide film 172 may include a metal formed of Ti, W, Ru, Nb, Mo, Hf, Ni, Co, Pt, Yb, Tb, Dy, Er, or Pd. For example, the metal silicide film 172 may be formed of, but not limited to, titanium silicide.

An insulating liner 142 may be disposed on the plurality of source/drain regions 130, the plurality of metal silicide films 172, and the plurality of outer insulating spacers 118. On the substrate 102, the plurality of source/drain regions 130, the plurality of metal silicide films 172, and the plurality of outer insulating spacers 118 may be covered by an insulating liner 142. In some embodiments, the insulating liner 142 may be omitted. An inter-gate insulating film 144 may be disposed on the insulating liner 142. When the insulating liner 142 is omitted, the inter-gate insulating film 144 may contact the plurality of source/drain regions 130. In an embodiment, the insulating liner 142 may be formed of, but not limited to, silicon nitride, SiCN, SiBN, SiON, SiOCN, SiBCN, or a combination thereof. The inter-gate insulating film 144 may be formed of, but not limited to, a silicon oxide film.

Side walls of each of the plurality of sub-gate portions 160S included in the plurality of gate lines 160 may be spaced apart from the source/drain region 130 with the gate dielectric film 152 disposed therebetween. The gate dielectric film 152 may be disposed between the sub-gate portion 160S included in the gate line 160 and each of the first nanosheet N1, the second nanosheet N2, and the third nanosheet N3, and disposed between the sub-gate portion 160S included in the gate line 160 and the source/drain region 130.

The plurality of nanosheet stack NSS may be disposed on the fin top surface FT of each of the plurality of fin-type active regions F1 in areas where the plurality of fin-type active regions F1 and the plurality of gate lines 160 intersect each other, and may face the fin top surface of the fin-type active region F1 at a position spaced apart from the fin-type active region F1. On the substrate 102, a plurality of nanosheet transistors may be disposed on portions where the plurality of fin-type active regions F1 and the plurality of gate lines 160 intersect each other.

A plurality of source/drain contacts CA may be disposed on the plurality of source/drain regions 130. Each of the plurality of source/drain contacts CA may pass through the inter-gate insulating film 144 and the insulating liner 142 in the vertical direction (Z direction) and may contact the metal silicide film 172. Each of the plurality of source/drain contacts CA may be configured to be electrically connected to the source/drain region 130 through the metal silicide film 172. Each of the plurality of source/drain contacts CA may be spaced apart from the main gate portion 160M with the outer insulating spacer 118 disposed therebetween in the first horizontal direction (X direction).

The plurality of source/drain contacts CA may include a conductive barrier pattern 174 and a contact plug 176 sequentially stacked on the source/drain region 130. The conductive barrier pattern 174 may be disposed on a bottom surface and a side wall of the contact plug 176. For example, the conductive barrier pattern 174 may surround and contact a bottom surface and a side wall of the contact plug 176. Each of the plurality of source/drain contacts CA may pass through the inter-gate insulating film 144 and the insulating liner 142 and may extend along the vertical direction (Z direction). The conductive barrier pattern 174 may be located between the metal silicide film 172 and the contact plug 176. The conductive barrier pattern 174 may have a surface contacting the metal silicide film 172 and a surface contacting the contact plug 176.

In some embodiments, the conductive barrier pattern 174 may be formed of a metal or metal nitride. For example, the conductive barrier pattern 174 may be formed of, but not limited to, Ti, Ta, W, TiN, TaN, WN, WCN, TiSiN, TaSiN, WSiN, or a combination thereof. The contact plug 176 may be formed of, but not limited to, molybdenum (Mo), copper (Cu), tungsten (W), cobalt (Co), ruthenium (Ru), manganese (Mn), titanium (Ti), tantalum (Ta), or aluminum (Al), a combination thereof, or an alloy thereof.

The source/drain contact CA adjacent to the via power rail VPR from among the plurality of source/drain contacts CA may be spaced apart from the via power rail VPR in the second horizontal direction (Y direction) (see FIG. 2).

An upper insulating structure 180 may be disposed on a top surface of each of the plurality of source/drain contacts CA, the plurality of capping insulating patterns 168, and the inter-gate insulating film 144. For example, the top surface of each of the plurality of source/drain contacts CA, the plurality of capping insulating patterns 168, and the inter-gate insulating film 144 may be covered by an upper insulating structure 180. The upper insulating structure 180 may include an etch stop film 182 and an interlayer insulating film 184 sequentially stacked on each of the plurality of source/drain contacts CA, the plurality of capping insulating patterns 168, and the inter-gate insulating film 144.

In some embodiments, the etch stop film 182 may be formed of silicon carbide (SiC), SiN, nitrogen-doped silicon carbide (SiC: N), SiOC, AlN, AlON, AlO, AlOC, or a combination thereof. The interlayer insulating film 184 may be formed of an oxide film, a nitride film, an ultra low-k (ULK) film having an ultra low dielectric constant K of about 2.2 to about 2.4, or a combination thereof. For example, the interlayer insulating film 184 may be formed of a tetraethyl orthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, or a combination thereof.

A plurality of source/drain via contacts VA may be disposed on the plurality of source/drain contacts CA. Each of the plurality of source/drain via contacts VA may pass through the upper insulating structure 180 to contact the source/drain contact CA. Each of the plurality of source/drain regions 130 may be configured to be electrically connected to the source/drain via contact VA through the metal silicide film 172 and the source/drain contact CA. A bottom surface of each of the plurality of source/drain via contacts VA may contact a top surface of the source/drain contact CA.

In some embodiments, each of the plurality of source/drain via contacts VA may include an upper area 121 and a lower area 123 (see FIG. 4). The upper area 121 of the source/drain via contact VA may pass through the interlayer insulating film 184. The upper area 121 may pass through the interlayer insulating film 184, and a side wall of the upper area 121 may contact the interlayer insulating film 184. The lower area 123 may be located at a lower end portion of the upper area 121. The lower area 123 may pass through the etch stop film 182.

In embodiments, the integrated circuit device 100 may include an air gap AG. For example, the etch stop film 182 may be formed to include a plurality of openings. The openings in the etch stop film 182 may expose upper surfaces of the outer insulating spacer 118, the insulating liner 142, and the inter-gate insulating film 144. The plurality of source/drain via contacts VA may be disposed in the openings. A width of a source/drain via in the first horizontal direction (X direction) may be less than a width of an opening in the etch stop film 182. Spaces between side walls of the etch stop film 182 and the plurality of source/drain via contacts VA may form a plurality of air gaps AG. The plurality of air gaps AG may be disposed between the plurality of source/drain via contacts VA and the etch stop film 182. the plurality of air gaps AG may overlap the lower area 123 of the source/drain via contact VA in the horizontal direction. In this case, a height of the air gap AG may be substantially the same as a height of the etch stop film 182. For example, a vertical level of a top surface of the air gap AG may be substantially the same as a vertical level of a top surface of the etch stop film 182. Also, a vertical level of a bottom surface of the air gap AG may be substantially the same as a vertical level of a bottom surface of the etch stop film 182. For example, the vertical level of the top surface of the air gap AG and the vertical level of the top surface of the etch stop film 182 may be colinear. Further, for example, the vertical level of the bottom surface of the air gap AG and the vertical level of the bottom surface of the etch stop film 182 may be colinear.

In an embodiment, each of a plurality of lower areas 123 may have a shape having a width that decreases as a vertical level increases. For example, a horizontal width of the lower area 123 may decrease toward the upper area 121. However, a shape of the lower area 123 is not limited thereto, and the shape of the lower area 123 may be variously formed.

In some embodiments, the air gap AG may surround the lower area 123 of the source/drain via contact VA in the horizontal direction. Accordingly, a shape of the air gap AG may correspond to a shape of the lower area 123. In an embodiment, the air gap AG may have an inverted trapezoidal shape with an upper surface longer than a lower surface. For example, a horizontal width of a top surface of the air gap AG may be greater than a horizontal width of a bottom surface of the air gap AG.

In some embodiments, the plurality of source/drain via contacts VA may respectively include a plurality of protrusions 123a. The plurality of protrusions 123a may each be disposed at a lower end portion of the lower area 123. The plurality of protrusions 123a may protrude toward the plurality of source/drain contacts CA. For example, upper portions of the conductive barrier pattern 174 and the contact plug 176 may form a concave shape in a source/drain contact of the plurality of source/drain contacts CA. A protrusion of the plurality of protrusions 123a may be disposed in the concave shape such that the plurality of protrusions 123a may protrude toward the plurality of source/drain contacts CA. The plurality of protrusions 123a may include curved surfaces convex toward the plurality of source/drain contacts CA.

In some embodiments, the plurality of source/drain contacts CA may include a plurality of recess portions R2. The recess portion R2 may be concave toward the source/drain region 130. Accordingly, a vertical level of a top surface of the conductive barrier pattern 174 may be equal to or higher than a vertical level of a top surface of the contact plug 176. In a process of forming the recess portion R2, upper portions of the conductive barrier pattern 174 and the contact plug 176 may be removed. A top surface of the recess portion R2 may include a concave curved surface. The recess portion R2 may contact the protrusion 123a of the source/drain via contact VA (see FIG. 4).

In an embodiment, the plurality of air gaps AG may be formed between the plurality of source/drain via contacts VA and the etch stop film 182, and a capacitance value of the integrated circuit device 100 may be reduced.

Also, the plurality of air gaps AG may be formed between the plurality of source/drain via contacts VA and the etch stop film 182, and the function of the integrated circuit device 100 may be improved. In detail, the capacitance and resistance of the integrated circuit device may be reduced by the air gap AG surrounding the source/drain via contact VA, and the RC delay of the integrated circuit device 100 may be reduced.

The air gap AG may be filled with, for example, a vacuum, a gas, or a gas mixture. For example, the air gap AG may include a gas mixture other than air.

Also, in a process of forming the protrusion 123a, the conductive barrier pattern 174 formed of a high-resistance material may be removed and the protrusion 123a having relatively low resistance may fill the place of the conductive barrier pattern 174, and the resistance of the integrated circuit device 100 may be reduced.

In some embodiments, the upper area 121, the lower area 123, and the protrusion 123a of the source/drain via contact VA may include the same material. For example, each of the upper area 121, the lower area 123, and the protrusion 123a may include a contact plug formed of, but not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof. In some embodiments, the plurality of source/drain via contacts VA may further include a conductive barrier pattern surrounding a part of the contact plug. The conductive barrier pattern included in the plurality of source/drain via contacts VA may be formed of a metal or metal nitride. For example, the conductive barrier pattern may be formed of, but not limited to, Ti, Ta, W, TiN, TaN, WN, WCN, TiSiN, TaSiN, WSiN, or a combination thereof.

In embodiments, the upper area 121, the lower area 123, and the protrusion 123a may be integrally formed. The source/drain via contact VA including the upper area 121, the lower area 123, and the protrusion 123a may have, but is not limited to, an anchor shape. In a case that the source/drain via contact VA has an anchor shape, structural stability may be improved. For example, the source/drain via contact VA including the upper area 121 and the lower area 123 may have a converging/diverging shape in the vertical direction (Z direction), with a reduced width disposed at a portion where the upper area 121 and the lower area 123 meet. A shape of the source/drain via contact VA may improve a structural stability of the integrated circuit device 100.

A gate contact CB may be disposed on the gate line 160. The gate contact CB may pass through the upper insulating structure 180 and the capping insulating pattern 168 in the vertical direction (Z direction) and may be connected to the gate line 160. A bottom surface of the gate contact CB may contact a top surface of the gate line 160.

In some embodiments, the gate contact CB may include a contact plug formed of, but not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof. In an embodiment, the gate contact CB may further include a conductive barrier pattern surrounding a part of the contact plug. The conductive barrier pattern included in the gate contact CB may be formed of a metal or metal nitride. For example, the conductive barrier pattern may be formed of, but not limited to, Ti, Ta, W, TiN, TaN, WN, WCN, TiSiN, TaSiN, WSiN, or a combination thereof.

The via power rail VPR and the via insulating spacer 190P may pass through the upper insulating structure 180, the capping insulating pattern 168, the gate line 160, the inter-gate insulating film 144, the insulating liner 142, and the device isolation film 112 in the vertical direction (Z direction). A portion of the gate line 160 through which the via power rail VPR and the via insulating spacer 190P pass in the vertical direction (Z direction) may be a portion disposed between a pair of adjacent nanosheet stacks NSS from among the plurality of nanosheet stacks NSS. The via power rail VPR may be spaced apart from the gate line 160 with the via insulating spacer 190P disposed therebetween in the horizontal direction, for example, the second horizontal direction (Y direction). The via power rail VPR and the via insulating spacer 190P may be spaced apart from the source/drain region 130 in the horizontal direction, for example, the second horizontal direction (Y direction).

The backside power structure PWS including the backside power rail BPW and the insulating liner structure ILS may be located at a position overlapping the gate line 160 in the vertical direction (Z direction). The backside power structure PWS may be spaced apart from the plurality of nanosheet stacks NSS with the device isolation film 112 disposed therebetween.

A top surface of each of the upper insulating structure 180, the plurality of source/drain via contacts VA, and the gate contact CB may be covered by an upper insulating film 192. A constituent material of the upper insulating film 192 is substantially the same as a constituent material of the interlayer insulating film 184 described above.

A plurality of upper wiring layers M1 may pass through the upper insulating film 192. Each of the plurality of upper wiring layers M1 may be connected to one source/drain via contact VA selected from among the plurality of source/drain via contacts VA or to one gate contact CB selected from among the plurality of gate contacts CB located under the plurality of upper wiring layers M1. Each of the plurality of upper wiring layers M1 may be formed of, but not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof.

The plurality of upper wiring layers M1 may include a power connection conductive layer PCL connected to the via power rail VPR on the via power rail VPR. One source/drain via contact VA selected from among the plurality of source/drain via contacts VA may be connected between the source/drain contact CA and the power connection conductive layer PCL at a position spaced apart from the via power rail VPR in the second horizontal direction (Y direction). The source/drain region 130 connected to the via power rail VPR from among the plurality of source/drain regions 130 may be electrically connected to the via power rail VPR through the source/drain contact CA, the source/drain via contact VA, and the power connection conductive layer PCL.

A frontside wiring structure FWS may be disposed on the plurality of upper wiring layers M1 and the upper insulating film 192. The frontside wiring structure FWS may include a plurality of wiring layers MN1, a plurality of via contacts CT1, and an interlayer insulating film 194 covering the plurality of wiring layers MN1 and the plurality of via contacts CT1. The via power rail VPR may be connected to one wiring layer MN1 selected from among the plurality of wiring layers MN1 through the upper wiring layer M1 and the via contact CT1. A constituent material of the plurality of wiring layers MN1 and the plurality of via contacts CT1 is substantially the same as a constituent material of the plurality of upper wiring layers M1 described above. A constituent material of the interlayer insulating film 194 is substantially the same as a constituent material of the interlayer insulating film 184 described above.

The backside surface 102B of the substrate 102 and the backside power rail BPW may be covered by a backside wiring structure (not shown). The backside wiring structure may have substantially the same configuration as that described for the frontside wiring structure FWS. However, the backside wiring structure may include a wiring layer connected to the backside power rail BPW.

Methods of manufacturing an integrated circuit device according to an embodiment will now be described.

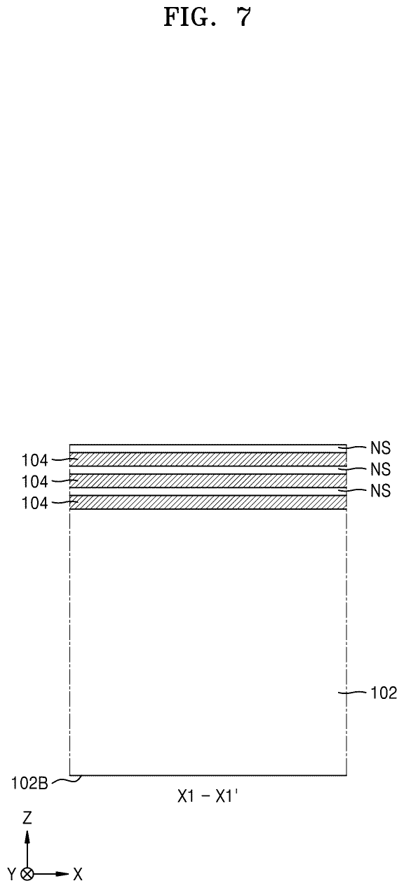

FIGS. 7 to 19 are cross-sectional views illustrated according to a process order to describe a method of manufacturing an integrated circuit device, taken along line X1-X1′ of FIG. 2, according to an embodiment.

With reference to FIGS. 7 to 19, a method of manufacturing the integrated circuit device 100 of FIGS. 2 to 6 is described. In FIGS. 7 to 19, the same members as those in FIGS. 2 to 6 are denoted by the same reference numerals, and a detailed description thereof may be omitted.

Referring to FIG. 7, the substrate 102 may be prepared, and a plurality of sacrificial semiconductor layers 104 and a plurality of nanosheet semiconductor layers NS may be alternately stacked on a frontside surface of the substrate 102.

The plurality of sacrificial semiconductor layers 104 and the plurality of nanosheet semiconductor layers NS may be formed of semiconductor materials having different etch selectivities. In embodiments, the plurality of nanosheet semiconductor layers NS may be formed of an Si layer, and the plurality of sacrificial semiconductor layers 104 may be formed of a SiGe layer. In embodiments, Ge content in the plurality of sacrificial semiconductor layers 104 may be constant. The SiGe layer forming the plurality of sacrificial semiconductor layers 104 may have a constant Ge content selected within a range of about 5 atom % to about 60 atom %, for example, about 10 atom % to about 40 atom %. Ge content in the SiGe layer forming the plurality of sacrificial semiconductor layers 104 may be selected in various ways as needed.

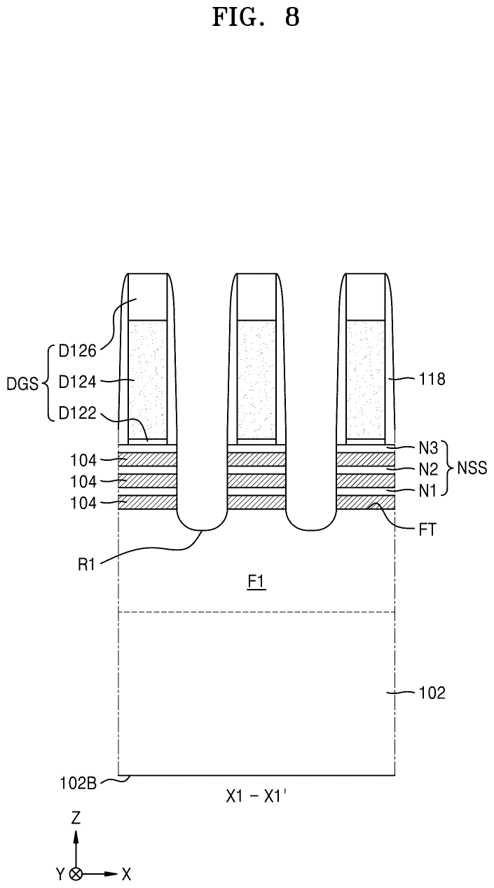

Referring to FIG. 8, a plurality of fin-type active regions F1 protruding from the substrate 102 may be formed by etching parts of the plurality of sacrificial semiconductor layers 104, the plurality of nanosheet semiconductor layers NS and the substrate 102 in a resultant structure of FIG. 7, and the device isolation film 112 (see FIG. 5) covering a side wall of each of the plurality of fin-type active regions F1 may be formed. A stacked structure of the plurality of sacrificial semiconductor layers 104 and the plurality of nanosheet semiconductor layers NS may remain on the fin top surface FT of each of the plurality of fin-type active regions F1.

A plurality of dummy gate structures DGS may be formed on the stacked structure of the plurality of sacrificial semiconductor layers 104 and the plurality of nanosheet semiconductor layers NS. Each of the plurality of dummy gate structures DGS may extend along the second horizontal direction (Y direction). Each of the plurality of dummy gate structures DGS may have a structure in which an oxide film D122, a dummy gate layer D124, and a capping layer D126 are sequentially stacked. In embodiments, the oxide film D122 may be obtained by oxidizing a surface of each of the plurality of sacrificial semiconductor layers 104 and the plurality of nanosheet semiconductor layers NS (see FIG. 7). The dummy gate layer D124 may be formed of polysilicon, and the capping layer D126 may be formed of a silicon nitride film.

After a plurality of outer insulating spacers 118 covering side walls of the plurality of dummy gate structures DGS are formed, the plurality of recesses R1 may be formed on the fin-type active region F1 by etching parts of the plurality of sacrificial semiconductor layers 104 and the plurality of nanosheet semiconductor layers NS and a part of the fin-type active region F1 by using the plurality of dummy gate structures DGS and the plurality of outer insulating spacers 118 as etch masks and dividing the plurality of nanosheet semiconductor layers NS into the plurality of nanosheet stacks NSS each including the first nanosheet N1, the second nanosheet N2, and the third nanosheet N3. To form the plurality of recesses R1, etching may be performed by using dry etching, wet etching, or a combination thereof.

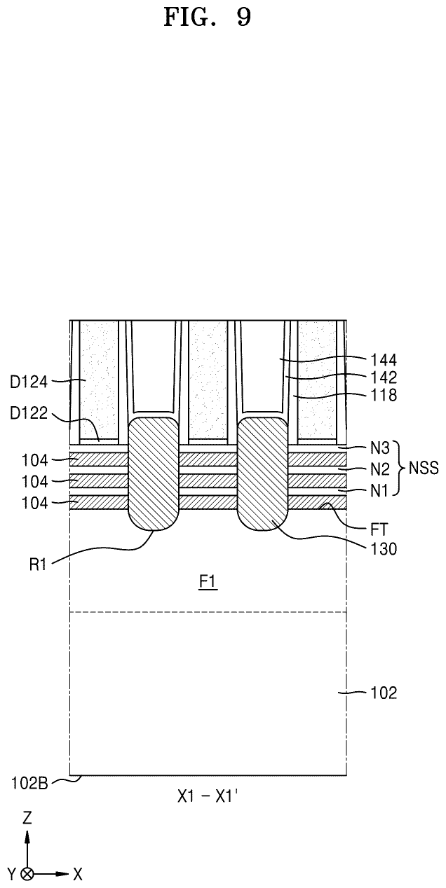

Referring to FIG. 9, the plurality of source/drain regions 130 filling the plurality of recesses R1 may be formed in a resultant structure of FIG. 8. To form the plurality of source/drain regions 130, a semiconductor material may be epitaxially grown from a surface of the fin-type active region F1 exposed through bottom surfaces of the plurality of recesses R1 and a side wall of each of the first nanosheet N1, the second nanosheet N2, and the third nanosheet N3 included in the nanosheet stack NSS.

The insulating liner 142 may be formed, the inter-gate insulating film 144 may be formed on the insulating liner 142, and then top surfaces of the plurality of capping layers D126 may be exposed by etching a part of each of the insulating liner 142 and the inter-gate insulating film 144. The dummy gate layer D124 may be exposed by removing the plurality of capping layers D126, and the insulating liner 142 and the inter-gate insulating film 144 may be partially removed so that a top surface of the inter-gate insulating film 144 and a top surface of the dummy gate layer D124 are at substantially the same level.

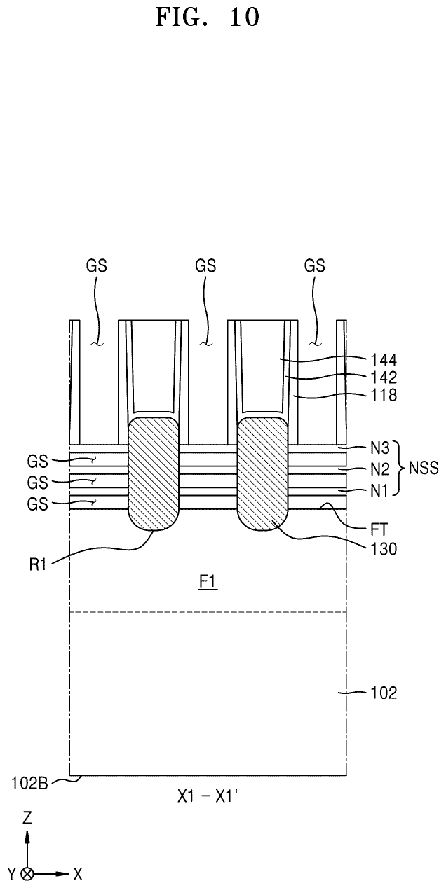

Referring to FIG. 10, a gate space GS may be provided by removing the dummy gate layer D124 and the oxide film D122 under the dummy gate layer D124 from a resultant structure of FIG. 9, and the plurality of nanosheet stacks NSS may be exposed through the gate space GS. The gate space GS may be extended to a space between the first nanosheet N1, the second nanosheet N2, and the third nanosheet N3 and a space between the first nanosheet N1 and the fin top surface FT by removing the plurality of sacrificial semiconductor layers 104 remaining on the fin-type active region F1 through the gate space GS. In embodiments, to selectively remove the plurality of sacrificial semiconductor layers 104, an etch selectivity difference between the first nanosheet N1, the second nanosheet N2, and the third nanosheet N3 and the plurality of sacrificial semiconductor layers 104 may be used.

To selectively remove the plurality of sacrificial semiconductor layers 104, a liquid or gaseous etchant may be used. In embodiments, to selectively remove the plurality of sacrificial semiconductor layers 104, a CH3COOH-based etchant, for example, an etchant including a mixture of CH3COOH, HNO3, and HF or an etchant including a mixture of CH3COOH, H2O2, and HF may be used, but the inventive concept is not limited thereto.

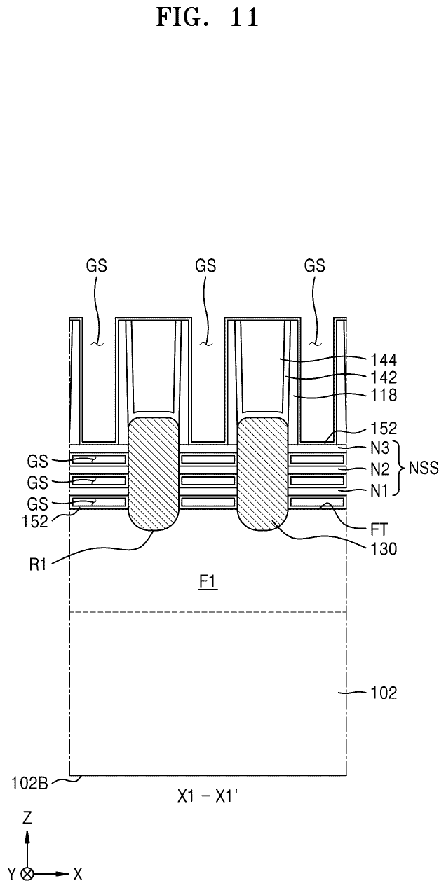

Referring to FIG. 11, the gate dielectric film 152 covering exposed surfaces of the first nanosheet N1, the second nanosheet N2, and the third nanosheet N3 and the fin-type active region F1 may be formed in a resultant structure of FIG. 10. An ALD process may be used to form the gate dielectric film 152.

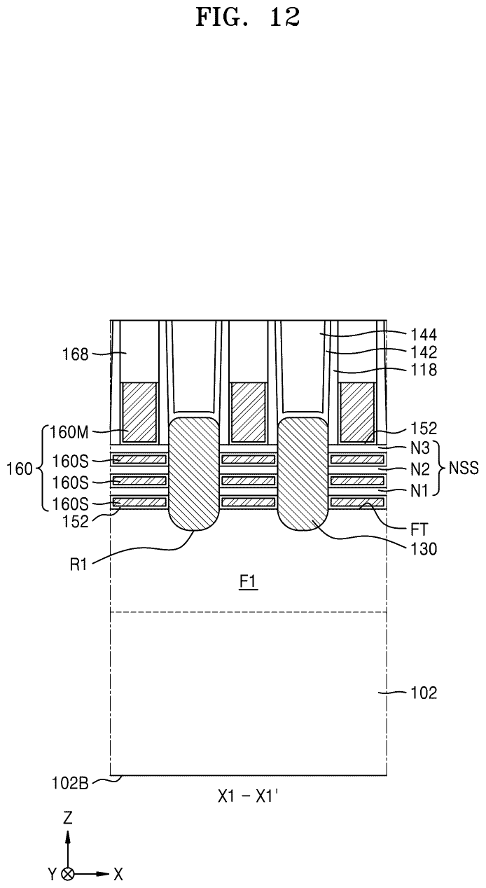

Referring to FIG. 12, the gate line 160 filling the gate space GS (see FIG. 11) and covering a top surface of the inter-gate insulating film 144 on the gate dielectric film 152 and the capping insulating pattern 168 covering a top surface of each of the gate line 160 and the gate dielectric film 152 in the gate space GS may be formed.

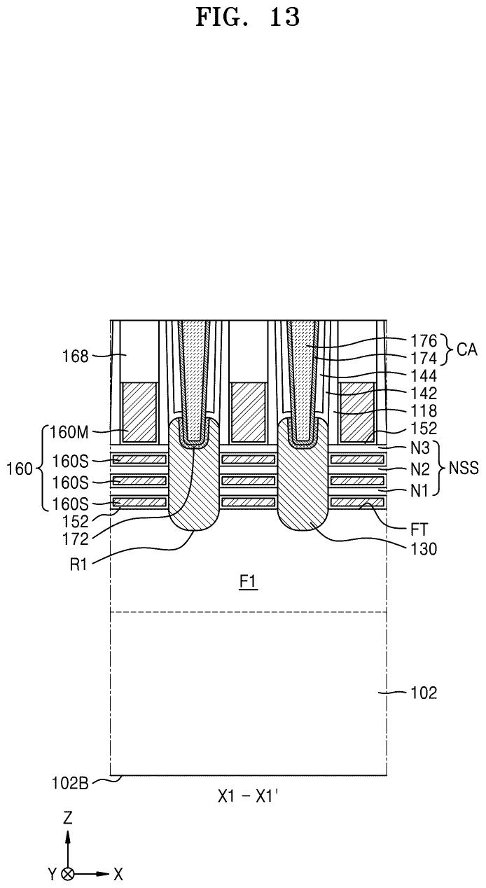

Referring to FIG. 13, after a source/drain contact hole passing through an insulating structure including the insulating liner 142 and the inter-gate insulating film 144 to expose the source/drain region 130 is formed in a resultant structure of FIG. 12, the source/drain contact hole may be extended toward the substrate 102 by removing a portion of the source/drain region 130 through the source/drain contact hole. The source/drain contact hole may be extended toward the substrate 102 by using an anisotropic etching process. The metal silicide film 172 may be formed on the source/drain region 130 exposed at the bottom of the source/drain contact hole. In some embodiments, to form the metal silicide film 172, a metal liner (not shown) conformally covering an exposed surface of the source/drain region 130 may be formed, and a process of inducing a reaction between the source/drain region 130 and a metal of the metal liner through heat treatment may be performed. After the metal silicide film 172 is formed, a remaining portion of the metal liner may be removed. A part of the source/drain region 130 may be consumed during a process of forming the metal silicide film 172. For example, at least a portion of the metal silicide film 172 may contact a lower surface of the insulating liner 142. In some embodiments, when the metal silicide film 172 is formed of a titanium silicide film, the metal liner may be formed of a Ti film. The source/drain contact CA including the conductive barrier pattern 174 and the contact plug 176 may be formed on the metal silicide film 172.

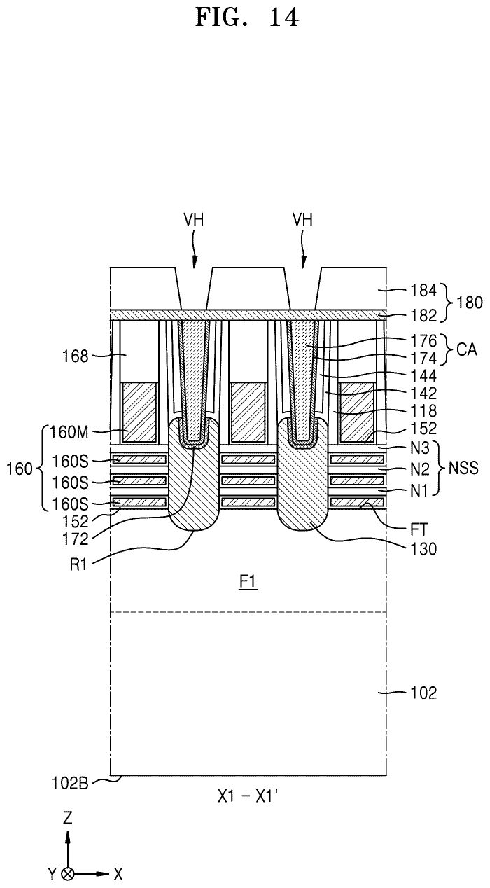

Referring to FIG. 14, the upper insulating structure 180 may be formed by sequentially forming the etch stop film 182 and the interlayer insulating film 184 covering a top surface of each of the inter-gate insulating film 144, a plurality of source/drain contacts CA, and a plurality of capping insulating patterns 168 in a resultant structure of FIG. 13. A plurality of via holes VH may be formed by etching the interlayer insulating film 184. In this case, a process of forming the plurality of via holes VH by etching the interlayer insulating film 184 may be stopped on the etch stop film 182.

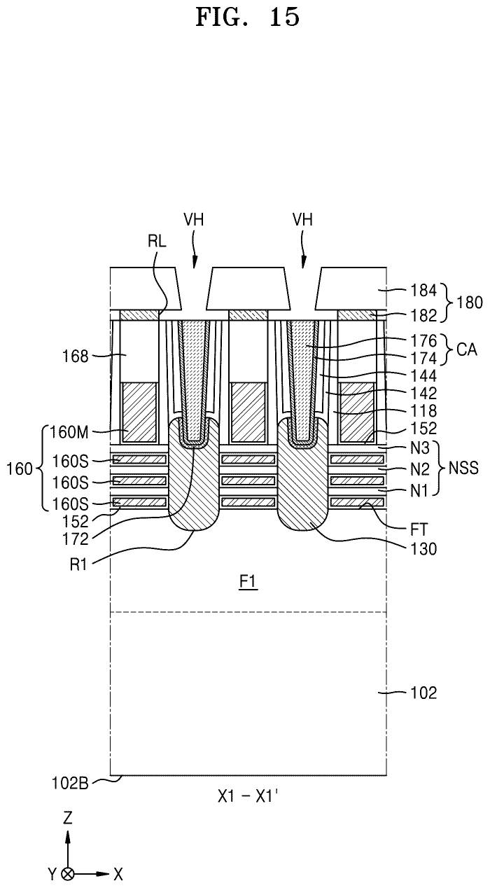

Referring to FIG. 15, a horizontal recess RL may be formed by etching a part of the etch stop film 182 in a resultant structure of FIG. 14. The horizontal recess RL may be formed by using, but not limited to, wet etching. In this case, a vertical level of a top surface of the horizontal recess RL may be the same as a vertical level of a top surface of the etch stop film 182 and a vertical level of a bottom surface of the horizontal recess RL may be the same as a vertical level of a bottom surface of the etch stop film 182. For example, the vertical level of the top surface of the horizontal recess RL and the vertical level of the top surface of the etch stop film 182 may be colinear. Further, for example, the vertical level of the bottom surface of the horizontal recess RL and the vertical level of the bottom surface of the etch stop film 182 may be colinear. In this case, a horizontal depth of the horizontal recess RL may be a depth at which the structural stability of the integrated circuit device 100 may be maintained. The depth at which the structural stability of the integrated circuit device 100 may be maintained may be within a range of depths at which the structural stability of the integrated circuit device 100 may be maintained. For example, the horizontal depth of the horizontal recess RL may be variously formed. The etching of the etch stop film 182 and the forming of the horizontal recess RL may expose side walls of the etch stop film 182. The side walls of the etch stop film 182 may be disposed below the interlayer insulating film 184. The horizontal recess RL may define an opening in the etch stop film 182.

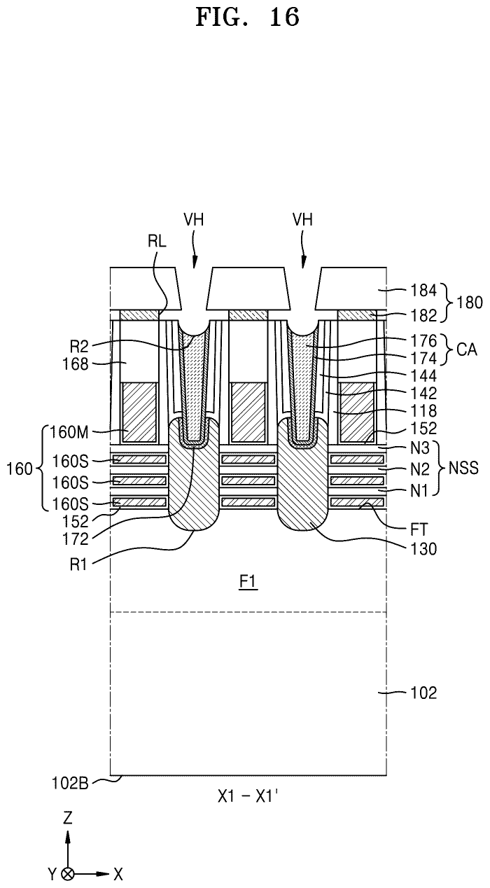

Referring to FIG. 16, a plurality of recess portions R2 may be formed by etching parts of the plurality of source/drain contacts CA in a resultant structure of FIG. 15. To form the plurality of recess portions R2, etching may be performed by using dry etching, wet etching, or a combination thereof.

The plurality of recess portions R2 may have concave shapes toward the source/drain regions 130. The plurality of recess portions R2 may be formed by etching upper parts of the conductive barrier pattern 174 and the contact plug 176. Accordingly, a vertical level of a top surface of the conductive barrier pattern 174 may be equal to or higher than a vertical level of a top surface of the contact plug 176. A top surface of the recess portion R2 may include a concave curved surface. Also, a vertical level of a top surface of the conductive barrier pattern 174 and a vertical level of a top surface of the contact plug 176 may be equal to or lower than a vertical level of a top surface of the capping insulating pattern 168.

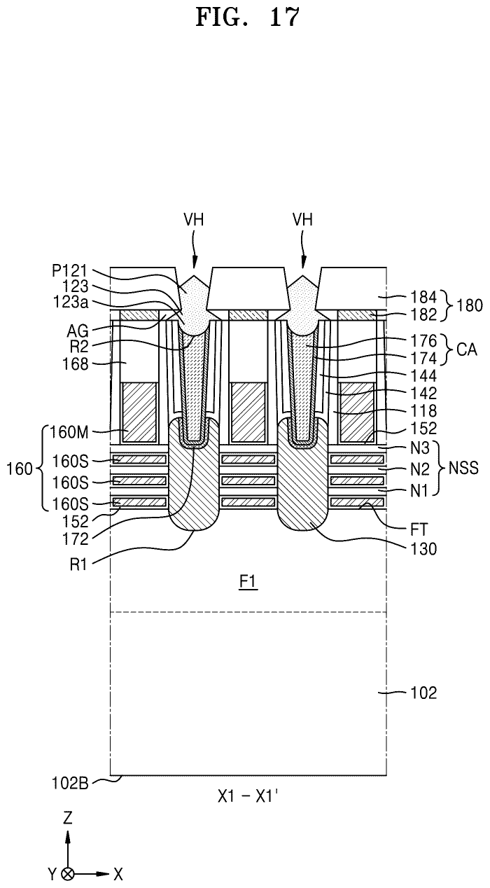

Referring to FIG. 17, a first preliminary conductive pattern may be grown from a top surface of the recess portion R2 in a resultant structure of FIG. 16 in the vertical direction (Z direction). The first preliminary conductive pattern may be formed by using selective growth. Accordingly, the first preliminary conductive pattern may be grown from the top surface of the recess portion R2 toward the via hole VH. The first preliminary conductive pattern may include the protrusion 123a disposed in the recess portion R2, the lower area 123 disposed in a part of the horizontal recess RL, and a preliminary upper area P121 disposed in a lower portion of the via hole VH. For example, the first preliminary conductive pattern may include the protrusion 123a, which may fill the recess portion R2, the lower area 123, which may fill a part of the horizontal recess RL, and a preliminary upper area P121, which may fill a lower portion of the via hole VH.

The preliminary upper area P121 and the lower area 123 of the first preliminary conductive pattern may have an anchor shape. The anchor shape may have a converging portion corresponding to the preliminary upper area P121 and a diverging portion corresponding to the lower area 123. The converging/diverging shape may be disposed in the vertical direction (Z direction), and may have a reduced width disposed at a portion where the preliminary upper area P121 and the lower area 123 meet.

The air gap AG may be formed in a process of growing the first preliminary conductive pattern. The air gap AG may be formed between the lower area 123 and the etch stop film 182 in the horizontal direction. The air gap AG may surround the lower area 123 in the horizontal direction.

In embodiments, a plurality of air gaps AG may be formed between a plurality of source/drain via contacts VA and the etch stop film 182, and a capacitance value of the integrated circuit device 100 may be reduced. For example, the plurality of air gaps AG may be formed between a plurality of source/drain via contacts VA and side walls of the etch stop film 182. A volume of an air gap of the plurality of air gaps AG may be less than a volume of the horizontal recess RL.

Also, the plurality of air gaps AG may be formed between the plurality of source/drain via contacts VA and the etch stop film 182, and the function of the integrated circuit device 100 may be improved. In detail, the air gap AG may surround the source/drain via contact VA, and the capacitance and resistance of the integrated circuit device may be reduced, and the RC delay of the integrated circuit device 100 may be reduced.

Also, in a process of forming the protrusion 123a, the conductive barrier pattern 174 having a high resistance material may be removed and the protrusion 123a having relatively low resistance may fill the place of the conductive barrier pattern 174, and the resistance of the integrated circuit device 100 may be reduced.

The air gap AG may be filled with, for example, a vacuum, a gas, or a gas mixture. For example, the air gap AG may include a gas mixture other than air.

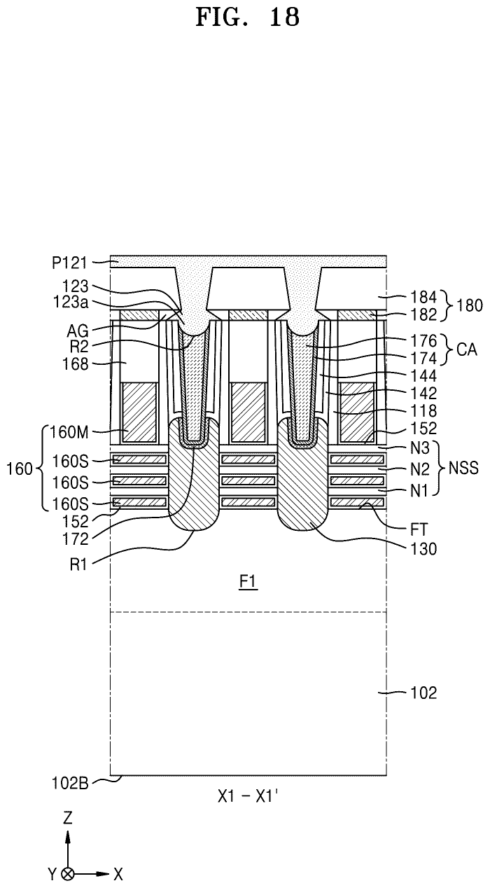

Referring to FIG. 18, a second preliminary conductive pattern may be disposed on the first preliminary conductive pattern in a resultant structure of FIG. 17. The second preliminary conductive pattern may be deposited on the first preliminary conductive pattern and the interlayer insulating film 184. For example, the second preliminary conductive pattern may be deposited by using, but not limited to, chemical vapor deposition (CVD). The second preliminary conductive pattern may include a preliminary upper area P121 filling an upper portion of the via hole VH and covering the interlayer insulating film 184.

The first preliminary conductive pattern and the second preliminary conductive pattern may be formed of the same material. For example, each of the first preliminary conductive pattern and the second preliminary conductive pattern may include a contact plug formed of, but not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof.

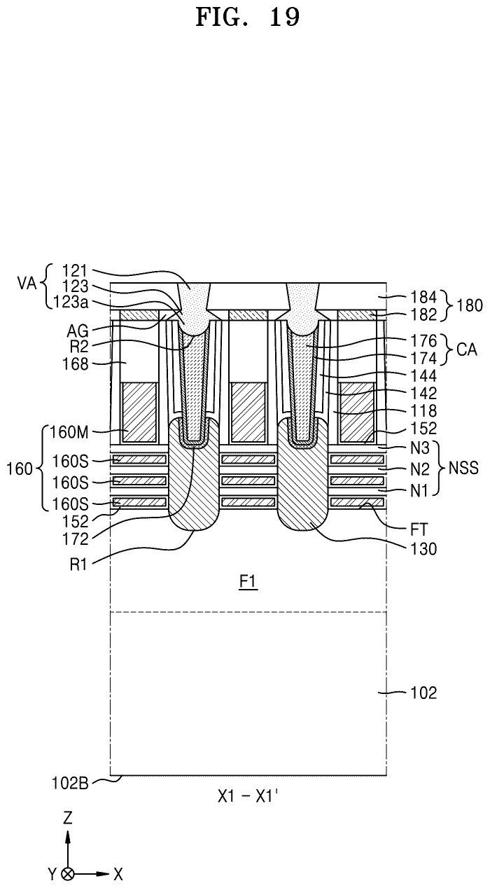

Referring to FIG. 19, the source/drain via contact VA may be formed by removing parts of the interlayer insulating film 184 and the second preliminary conductive pattern in a resultant structure of FIG. 18. The source/drain via contact VA may be formed by removing parts of the interlayer insulating film 184, the first preliminary conductive pattern, and the second preliminary conductive pattern in a resultant structure of FIG. 18. The source/drain via contact VA may be formed by using a chemical mechanical polishing (CMP) process or the like.

The gate contact CB and the via power rail VPR may be simultaneously or sequentially formed with the source/drain via contact VA described with reference to FIGS. 14 to 19. An order of forming the gate contact CB and the via power rail VPR is not particularly limited and structures may be formed in different orders.

Referring back to FIGS. 3 to 6, the upper insulating film 192 and a plurality of upper wiring layers M1 may be disposed on the upper insulating structure 180. The plurality of upper wiring layers M1 may pass through the upper insulating film 192 and may be connected to the source/drain via contact VA. Further, the gate contact CB and the via power rail VPR may be formed. The plurality of upper wiring layers M1 may be disposed on the via power rail VPR. The plurality of upper wiring layers M1 may include the power connection conductive layer PCL connected to the via power rail VPR. The frontside wiring structure FWS may be disposed on the upper insulating film 192 and the plurality of upper wiring layers M1.

A part of the substrate 102 may be removed from the backside surface 102B of the substrate 102. For example, the substrate 102 may be thinned and the backside surface 102B of the substrate 102 may be disposed closer to the fin-type active region F1 in the vertical direction (Z direction). To remove a part of the substrate 102, at least one process selected from among a mechanical grinding process, a CMP process, a wet etching process, or a combination thereof may be used.

The integrated circuit device 100 of the inventive concept may be manufactured by forming the backside power structure PWS including the backside power rail BPW and the insulating liner structure ILS, and forming a backside wiring structure (not shown) on the backside surface 120B of the substrate 102.

As described above, embodiments have been illustrated in the drawings and described in the specification. While embodiments have been described using specific terms, this is only used for the purpose of explaining the technical idea of the inventive concept and is not used to limit the meaning and scope of the inventive concept described in the claims. Hence, it will be understood by one of ordinary skill in the art that various modifications and other equivalent embodiments may be made therefrom. Accordingly, the technical scope of the inventive concept should be defined by the following claims.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a fin-type active region extending in a first horizontal direction on a substrate;
a gate line disposed on the fin-type active region on the substrate and extending in a second horizontal direction intersecting the first horizontal direction;
a source/drain region disposed on the fin-type active region and disposed adjacent to the gate line in the first horizontal direction;
a source/drain contact disposed on the source/drain region;
an upper insulating structure disposed on the gate line and comprising an etch stop film and an interlayer insulating film;
a source/drain via contact passing through the upper insulating structure and connected to the source/drain contact; and
an air gap disposed between the etch stop film and the source/drain via contact and overlapping a part of the source/drain via contact in a horizontal direction.

2. The integrated circuit device of claim 1, wherein
a vertical level of a top surface of the air gap and a vertical level of a top surface of the etch stop film are colinear, and
a vertical level of a bottom surface of the air gap and a vertical level of a bottom surface of the etch stop film are colinear.

3. The integrated circuit device of claim 1, wherein the source/drain via contact comprises:
an upper area passing through the interlayer insulating film; and
a lower area located at a lower end portion of the upper area and passing through the etch stop film.

4. The integrated circuit device of claim 3, wherein the lower area has a shape having a horizontal width that decreases toward the upper area.

5. The integrated circuit device of claim 3, wherein the air gap surrounds the lower area in the horizontal direction.

6. The integrated circuit device of claim 3, wherein the source/drain via contact further comprises a protrusion protruding from the lower area toward the source/drain contact.

7. The integrated circuit device of claim 6, wherein the source/drain contact comprises a recess portion contacting the protrusion.

8. The integrated circuit device of claim 6, wherein the source/drain contact comprises a conductive barrier pattern and a contact plug,
wherein a vertical level of a top surface of the conductive barrier pattern is greater than or equal to a vertical level of a top surface of the contact plug.

9. The integrated circuit device of claim 3, wherein the upper area and the lower area are formed of a same material.

10. The integrated circuit device of claim 1, wherein the air gap has an inverted trapezoidal shape with an upper surface longer than a lower surface.

11. A method of manufacturing an integrated circuit device, the method comprising:
forming a source/drain region on a substrate and a source/drain contact on the source/drain region;
forming, on the source/drain contact, an upper insulating structure comprising an etch stop film and an interlayer insulating film disposed on the etch stop film;
forming a via hole in the interlayer insulating film;
forming a horizontal recess in the etch stop film;
forming a recess portion in a part of the source/drain contact; and
forming a source/drain via contact in the recess portion, in a portion of the horizontal recess, and in the via hole.

12. The method of claim 11, wherein the forming of the horizontal recess comprises forming the horizontal recess having a vertical level of a top surface of the horizontal recess colinear with a vertical level of a top surface of the etch stop film and a vertical level of a bottom surface of the horizontal recess colinear with a vertical level of a bottom surface of the etch stop film.

13. The method of claim 11, wherein the forming of the recess portion comprises etching upper portions of a conductive barrier pattern and a contact plug of the source/drain contact.

14. The method of claim 11, wherein the forming of the source/drain via contact comprises growing the source/drain via contact in a vertical direction from a top surface of the recess portion.

15. The method of claim 14, wherein the forming of the source/drain via contact comprises:
growing a first preliminary conductive pattern filling the recess portion, the portion of the horizontal recess, and a lower portion of the via hole;
depositing, on the first preliminary conductive pattern, a second preliminary conductive pattern covering an upper portion of the via hole and the interlayer insulating film; and
forming the source/drain via contact by etching the interlayer insulating film and the second preliminary conductive pattern.

16. The method of claim 11, wherein the forming of the source/drain via contact comprises further forming an air gap disposed between the etch stop film and the source/drain via contact in a horizontal direction and overlapping a part of the source/drain via contact in the horizontal direction.

17. An integrated circuit device comprising:
a fin-type active region extending in a first horizontal direction on a substrate;
a nanosheet stack facing a fin top surface of the fin-type active region at a position spaced apart from the fin top surface in a vertical direction and comprising at least one nanosheet;
a gate line surrounding the at least one nanosheet on the fin-type active region and extending in a second horizontal direction intersecting the first horizontal direction;
a source/drain region disposed on the fin-type active region and disposed adjacent to the gate line in the first horizontal direction;
a source/drain contact disposed on the source/drain region;
a gate dielectric film contacting a bottom surface and side walls of the gate line;
a pair of insulating spacers disposed on the side walls of the gate line and spaced apart from the gate line in the first horizontal direction with the gate dielectric film disposed therebetween;
a capping insulating pattern disposed on a top surface of the gate line and a top surface of the gate dielectric film, and between the pair of insulating spacers;
an upper insulating structure disposed on the capping insulating pattern and the gate line and comprising an etch stop film and an interlayer insulating film; and
a source/drain via contact passing through the upper insulating structure and connected to the source/drain contact,
wherein the source/drain via contact comprises:
an upper area passing through the interlayer insulating film; and
a lower area disposed at a lower end portion of the upper area and passing through the etch stop film,
wherein the etch stop film comprises an air gap surrounding the lower area in a horizontal direction and overlapping the lower area in the horizontal direction.

18. The integrated circuit device of claim 17, wherein the lower area has a shape having a horizontal width that decreases toward the upper area.

19. The integrated circuit device of claim 17, wherein the source/drain via contact further comprises a protrusion protruding from the lower area toward the source/drain contact.

20. The integrated circuit device of claim 19, wherein the source/drain contact comprises a recess portion contacting the protrusion.
